(19) United States
(12) Patent Application Publication
(10) Pub. No.: US 2013/0140069 A1
(43) Pub. Date: Jun. 6, 2013

(54) CONDUCTIVE BONDING MATERIAL, ELECTRONIC COMPONENT, AND ELECTRONIC DEVICE

(71) Applicant: Fujitsu Limited, Kawasaki-shi (JP)

(72) Inventors: Masayuki KITAJIMA, Yokohama (JP); Takatoyo YAMAKAMI, Nagano (JP); Takashi KUBOTA, Chikuma (JP); Kuniko ISHIKAWA, Nagano (JP)

(73) Assignee: FUJITSU LIMITED, Kawasaki-shi (JP)

(21) Appl. No.: 13/693,376

(22) Filed: Dec. 4, 2012

(30) Foreign Application Priority Data
Dec. 6, 2011 (JP) 2011-266729

(51) Int. Cl. H01B 1/22; H05K 1/09

(52) U.S. Cl. CPC H01B 1/22; H05K 1/09
USPC 174/257; 252/512; 252/513; 252/514

(57) ABSTRACT

A conductive bonding material includes: copper particles coated with either gallium or gallium alloy; and either tin particles or tin alloy particles. An electronic component includes: a wiring board having electrode pads; a component mounted on the wiring board and having a plurality of electrodes; a sealing resin covering the component; and a plurality of terminals coupled to a wiring line in the wiring board to an external substrate, wherein the plurality of electrodes being coupled to the electrode pads through a conductive bonding material containing copper particles coated with either gallium or gallium alloy particles and either tin particles or tin alloy particles.

### CROSS-REFERENCE TO RELATED APPLICATION

This application is based upon and claims the benefit of priority of the prior Japanese Patent Application No. 2011-266729, filed on Dec. 6, 2011, the entire contents of which are incorporated herein by reference.

### FIELD

The embodiment discussed herein is related to a conductive bonding material, an electronic component containing the conductive bonding material, and an electronic device carrying the electronic component.

### BACKGROUND

An electronic component in which a chip component and the like are mounted on a wiring board is sometimes further mounted on a large-sized wiring board referred to as a mother board or a system board. In this case, with respect to the electronic component, components, such as a chip component and a semiconductor component are mounted on the wiring board using a solder paste as a conductive bonding material. The mounting described above is referred to as primary mounting. The primary mounting is performed by reflow heating (primary reflow), for example. After the chip component and the like are mounted on the wiring board as described above, the board with the components is sometimes entirely sealed with a sealing resin except for some components, such as an electrode. The electronic component sealed with a sealing resin as described above is referred to as a “resin module component”.

In an electronic device, the electronic component described above is mounted on a large-sized wiring board referred to as a mother board or a system board using a solder paste as a conductive bonding material. This mounting is referred to as secondary mounting. The secondary mounting is performed by reflow heating (secondary reflow), for example.

When the resin module component is subjected to the reflow (secondary reflow) treatment as described above, the conductive bonding material sometimes re-melts in the resin module component during the secondary reflow heating. When the conductive bonding material re-melts during the secondary reflow heating, there is a problem such that the melted conductive bonding material flows into a fine space in the electronic component to cause a short-circuit between electrodes. Such a space is produced due to a crack in the sealing resin, separation of the sealing resin from the chip component, or the like, for example.

Then, various examinations have been made for the purpose of precluding re-melting of the conductive bonding material during the secondary reflow heating.

Therefore, it has been demanded to provide a conductive bonding material capable of certainly achieving mounting by primary reflow heating and may preclude re-melting of the conductive bonding material during secondary reflow heating.

The following is reference document:
[Document 1] Japanese Laid-open Patent Publication No. 10-291087
[Document 2] Japanese National Publication of International Patent Application No. 11-514300

### SUMMARY

According to an aspect of the invention, a conductive bonding material includes: copper particles coated with either gallium or gallium alloy; and either tin particles or tin alloy particles.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a schematic sectional view illustrating a state where a space is formed in an electronic component during secondary reflow heating;

FIG. 1B is a schematic sectional view illustrating a state where a melted conductive bonding material enters the space in the electronic component to cause a short-circuit between electrodes;

FIGS. 2A to 2D are schematic views illustrating the bonding principle of the conductive bonding material of an embodiment;

FIG. 3 is a view illustrating the relationship between a primary mounting temperature profile and the melting point of gallium or gallium alloy;

FIG. 4 is a flow chart illustrating an example of a manufacturing process of an electronic component and an electronic device of the embodiment;

FIGS. 5A to 5G are schematic sectional views for explaining an example of the manufacturing process of the electronic component and the electronic device of the embodiment;

FIGS. 6A to 6G are schematic top views for explaining an example of the manufacturing process of the electronic component and the electronic device of the embodiment;

FIG. 7 is a schematic view illustrating metal mapping around Cu particles after reflow heating in Example 18;

FIG. 8 illustrates the relationship between the mass ratio and the melting point of gallium and copper alloy;

FIG. 9 illustrates the relationship between metal and ionization energy;

FIGS. 10A and 10B illustrate the property evaluation results based on a difference in metal components; and

FIG. 11 illustrates a diffusion length of Cu particles and surrounding metal after reflow heating.

### DESCRIPTION OF EMBODIMENT

Conductive Bonding Material

A conductive bonding material of this embodiment contains copper (Cu) particles coated with either gallium (Ga) or gallium (Ga) alloy, either tin (Sn) particles or tin (Sn) alloy particles, and a flux component, and may further contain other components.

Copper Particles Coated with Either Ga or Ga Alloy

The copper particles coated with either Ga or Ga alloy have a coating film containing Ga or Ga alloy on the copper particle surface.

Copper Particles

The shape, size, structure, and the like of the copper particles are not particularly limited and may be selected as appropriate according to the purpose.

As the shape of the copper particles, a globular shape, a spherical shape, a rugby ball shape, and the like are mentioned, for example. The structure of the copper particles may be a single layer structure or a laminated structure.

The volume average particle diameter of the copper particles is preferably 0.5 μm to 30 μm. When the volume average particle diameter is lower than 0.5 μm, it is difficult to produce copper particles with a small diameter and it sometimes becomes difficult to plate the same with Ga or Ga alloy. Moreover, it becomes difficult to add copper particles in a proportion of up to about 30% by mass, and printability of the conductive bonding material to a wiring board sometimes decreases.

The volume average particle diameter may be measured using a particle size distribution meter by a laser diffraction scattering method, for example.

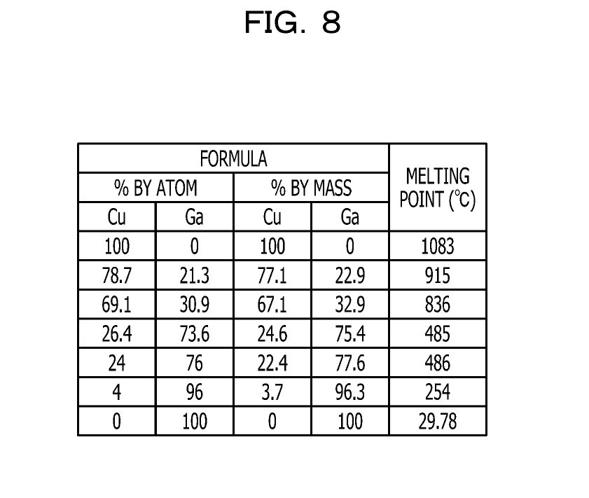

As the copper particles, it is preferable to use copper alloy particles containing an alloy of gallium and copper in addition to copper particles containing a copper simple substance. The reason is as follows. Since the melting point of Cu is 1,083° C. and the melting point of Ga is 29.78° C., a difference in the melting points of Cu and Ga is large. Therefore, when the copper alloy particles containing an alloy of gallium and copper are used, the melting point of the copper alloy particles may be further reduced as compared with the copper particles containing a copper simple substance as illustrated in FIG. 8, so that the melting point adjustment of copper particles is facilitated.

The mass ratio of Ga and Cu (Ga:Cu) in the copper alloy particles containing the gallium and the copper is preferably 20% by mass:80% by mass to 40% by mass:60% by mass.

The copper particles or the copper alloy particles are not particularly limited and manufactured one or a commercially-available item may be used as appropriate. As a method for producing the copper particles or the copper alloy particles, granulation by an atomizing method or the like is mentioned, for example. The atomizing method is a method including atomizing melted copper or copper alloy from a nozzle, causing a jet of an atomization medium (gas or liquid) to collide with the same for scattering to form liquid droplets, and cooling and solidifying the liquid droplets to form particles.

Gallium or Gallium Alloy

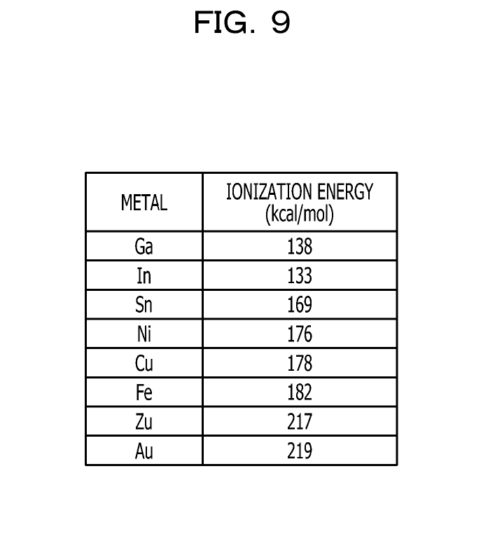

As the Ga alloy, it is preferable to use metal whose ionization tendency (Ionization energy: kcal/mol) is close to that of Ga as illustrated in FIG. 9, for example, from the viewpoint of forming a coating film on the copper particle surface by plating. Among the above, In, Sn, Ni, Cu, Fe, and the like are preferable.

Mentioned as the gallium alloy are, for example, gallium (Ga)—Ni (Ni) alloy, gallium (Ga)-copper (Cu) alloy, gallium (Ga)-tin (Sn) alloy, gallium (Ga)-gold (Au) alloy, Ga—In alloy, Ga—In—Sn alloy, Ga—In—Zn alloy, Ga—Zn alloy, and the like. Among the above, Ga—Ni alloy, Ga—Cu alloy, Ga—Sn alloy, and Ga—Au alloy are particularly preferable.

Mentioned as the Ga—Ni alloy are Ga-5.0Ni alloy containing Ga as the main component and containing Ni in a proportion of about 5.0% by mass and the like, for example.

Mentioned as the Ga—Cu alloy are Ga-3.7Cu alloy containing Ga as the main component and containing Cu in a proportion of about 3.7% by mass and the like, for example.

Mentioned as the Ga—Sn alloy are Ga-7.2Sn alloy containing Ga as the main component and containing Sn in a proportion of about 7.2% by mass and the like, for example.

Mentioned as the Ga—Au alloy are Ga-3.0Au alloy containing Ga as the main component and containing Au in a proportion of about 3.0% by mass and the like, for example.

Mentioned as the Ga—In alloy are Ga-24.5In alloy containing Ga as the main component and containing In in a proportion of about 24.5% by mass and the like, for example.

Mentioned as the Ga—In—Sn alloy are Ga-25In-13Sn alloy containing Ga as the main component and containing In in a proportion of about 25% by mass and Sn in a proportion of about 13% by mass and the like, for example.

Mentioned as the Ga—In—Zn alloy are Ga-29In-4Zn alloy containing Ga as the main component and containing In in a proportion of about 29% by mass and Zn in a proportion of about 4% by mass and the like, for example.

Mentioned as the Ga—Zn alloy are Ga-4.5Zn alloy containing Ga as the main component and containing Zn in a proportion of about 4.5% by mass and the like, for example.

The average thickness of the coating film containing either the gallium or the gallium alloy mentioned above is preferably 0.5 μm to 10 μm and more preferably 1 μm to 5 μm. When the average thickness exceeds 10 μm, the content of gallium or gallium alloy in the Cu particles is excessively high, which sometimes results in the formation of an intermetallic compound in which Cu and Ga have a granular shape and which does not have shine and is hard and brittle.

The average thickness of the coating film may be measured by a fluorescent X ray analyzing method, a method including polishing a coating film, or the like, for example.

A method for coating the copper particle surface with the gallium or the gallium alloy mentioned above is not particularly limited and may be selected as appropriate according to the purpose. For example, electroless plating and the like are mentioned.

Tin (Sn) Particles or Tin (Sn) Alloy Particles

The shape, size, structure, and the like of the Sn particles or the Sn alloy particles are not particularly limited and may be selected as appropriate according to the purpose.

As the shape of the Sn particles or the Sn alloy particles, a globular shape, a spherical shape, a rugby ball shape, and the like are mentioned, for example. The structure of the Sn particles or the Sn alloy particles may be a single layer structure or a laminated structure.

The Sn alloy particles are preferably either Sn—Bi—X alloy particles or Sn—Cu—X alloy particles (in which X is Ag, Ni, Zn, Pd, or In). Among the above, the Sn—Bi—Ag alloy particles and Sn—Cu—Ag alloy particles are particularly preferable in terms of solderability.

Mentioned as the Sn—Bi—Ag alloy are Sn-58Bi-1.0Ag alloy containing Sn as the main component and containing Bi in a proportion of about 58% by mass and Ag in a proportion of about 1.0% by mass and the like, for example.

Mentioned as the Sn—Cu—Ag alloy are Sn-0.5Cu-3.0Ag alloy containing Sn as the main component and containing Cu in a proportion of about 0.5% by mass and Ag in a proportion of about 3.0% by mass and the like, for example.

The volume average particle diameter of the Sn or the Sn alloy particles mentioned above is preferably 10 μm or more, more preferably 10 μm to 60 μm, and still more preferably 10 μm to 40 μm. When the volume average particle diameter is lower than 10 μm, the surface is severely oxidized and the solderability and the wettability to solder sometimes decrease. When the volume average particle diameter exceeds 60 μm, printability and diffusibility sometimes decrease.

The volume average particle diameter may be measured using a particle size distribution meter by a laser diffraction scattering method, for example.

The melting point of the Sn or the Sn alloy particles mentioned above is preferably 230° C. or lower and more preferably 139° C. to 230° C. When the melting point exceeds 230° C., the securing of bonding quality by precluding re-melting of solder in secondary mounting is not able to be sometimes achieved.

The melting point may be measured using DSC (Differential Scanning calorimetry), for example.

The Sn or the Sn alloy particles are not particularly limited and manufactured one or a commercially-available item may be used as appropriate. As a method for producing the Sn or the Sn alloy particles, granulation by an atomizing method or the like is mentioned, for example. The atomizing method is a method including atomizing melted copper or copper alloy from a nozzle, causing a jet of an atomization medium (gas or liquid) to collide with the same for scattering to form liquid droplets, and cooling and solidifying the liquid droplets to form particles.

The mixed ratio of the copper particles A coated with either the gallium or the gallium alloy and either the Sn particles or the Sn alloy particles B is preferably 20:80 to 50:50 and more preferably 30:70 to 50:50 in terms of the mass ratio (A:B).

When the mixed ratio of the copper particles is lower than the 20% by mass, the applicability of the conductive bonding material sometimes decreases. When the mixed ratio of the copper particles exceeds 50% by mass, the amount of the Sn or the Sn alloy particles decreases, so that the bonding strength sometimes decreases. The mixed ratio of the copper particles within the preferable range mentioned above is advantageous in that poor connection does not occur and the applicability does not decrease.

Flux Component

The flux component is not particularly limited and may be selected as appropriate according to the purpose and is preferably at least any one of an epoxy flux material and a rosin flux material. Among the above, when an epoxy flux material is used, the bonding strength may be further increased by curing the epoxy resin. Therefore, the use of the epoxy flux material is particularly preferable.

Epoxy Flux Material

The epoxy flux material contains epoxy resin, carboxylic acid, and a solvent and may further contain other components. The epoxy resin is not particularly limited and may be selected as appropriate according to the purpose. For example, a thermosetting epoxy resin, such as Bisphenol A type epoxy resin, Bisphenol F type epoxy resin, Novolac type epoxy resin, and modified epoxy resin thereof, and the like are mentioned. These substances may be used alone or in combination of two or more kinds thereof.

The carboxylic acid is not particularly limited and may be selected as appropriate according to the purpose. For example, saturated aliphatic dicarboxylic acid, unsaturated aliphatic dicarboxylic acid, cycloaliphatic dicarboxylic acid, amino group containing carboxylic acid, hydroxyl group containing carboxylic acid, heterocyclic dicarboxylic acid, or a mixture thereof is mentioned. Among the above, specifically, succinic acid, glutaric acid, adipic acid, azelaic acid, dodecanedioic acid, itaconic acid, mesaconic acid, cyclobutane dicarboxylic acid, L-glutamic acid, citric acid, malic acid, thiopropionic acid, thiodibutyl acid, and dithioglycolic acid are preferable.

Mentioned as the solvent are, for example, alcohols, such as methanol, ethanol, and propanol, an ethylene glycol solvent, diethylene glycol monohexyl ether, octanediol, and the like.

As the other components, additives, such as a thixotropic agent, a chelating agent, a surfactant, and an antioxidant, may be added, for example.

The epoxy flux material is not particularly limited and manufactured one or a commercially-available item may be used as appropriate.

Rosin Flux Material

The rosin flux material contains rosin resin, an active agent, and a solvent, and may further contain other components.

Mentioned as the rosin resin is one containing natural rosin resin or modified rosin resin as the main component. Mentioned as the modified rosin resin are polymerized rosin, hydrogenated rosin, phenol resin modified rosin, maleic acid modified rosin, and the like, for example.

The active agent is not particularly limited and may be selected as appropriate according to the purpose insofar as it is a component which reduces an oxide, a sulfide, a hydroxide, a chloride, a sulfate, and a carbonate present on the surface of metal to clean the metal. For example, diethylamine hydrochloride, diethylamine oxalate, and the like are mentioned.

Mentioned as the solvent are an ethylene glycol solvent, diethylene glycol monohexyl ether, octanediol, and the like, for example.

Mentioned as the other components are a thixotropic agent, a chelating agent, a surfactant, an antioxidant, and the like, for example.

The rosin flux material is not particularly limited and synthesized one or a commercially-available item may be used as appropriate.

The content of the flux component in the conductive bonding material is not particularly limited and may be selected as appropriate according to the purpose, and is preferably 8% by mass to 14% by mass.

Other Components

The conductive bonding material may contain other components in addition to the metal component and the flux component. Mentioned as the other components are a metal adsorption component, a dispersing agent, an antioxidant, and the like, for example.

The metal adsorption component is not particularly limited and may be selected as appropriate according to the purpose. For example, imidazole, benzoimidazole, alkylbenzoimidazole, benzotriazole, melcaptobenzothiazole, and the like are mentioned.

The conductive bonding material of this embodiment is prepared by mixing copper particles coated with either the gallium or the gallium alloy mentioned above, a metal component containing either the tin particles or the tin alloy particles mentioned above, the flux component, and maybe other components. The mixing method and the mixing conditions are not particularly limited and may be selected as appropriate according to the purpose. The mixing may be performed using a known mixing device, a stirring device, or the like. It is preferable to uniformly stir the components in a nonoxidizing atmosphere.

The conductive bonding material is used by being applied to electrode pads on a wiring board by printing or the like in, for example, an electronic component in which components, such as a chip component and a semiconductor component, are sealed with a sealing resin.

When the components, such as the chip component and the semiconductor component, are mounted on the conductive bonding material applied to the electrode pad, and then primary reflow heating is performed, the electrode pads and electrodes of the components, such as the chip component and the semiconductor component, are connected. Then, the components, such as the chip component and the semiconductor component, on the wiring board are sealed with a sealing resin.

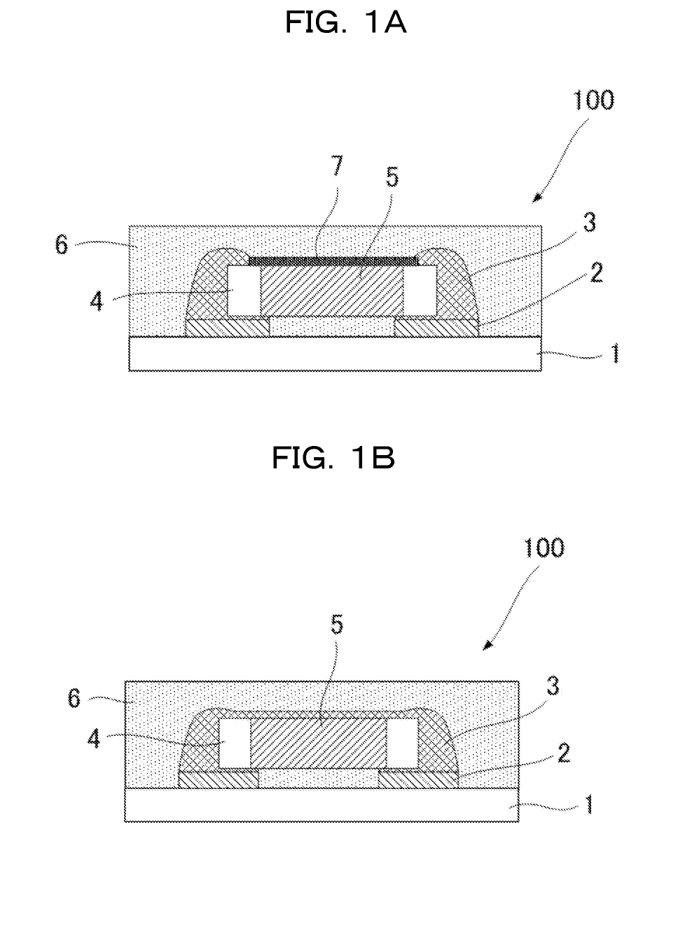

Next, the sealed electronic component is connected to an external printed-circuit board or the like. At this time, terminals of the electronic component and lead terminals of the printed-circuit board are connected by secondary reflow heating. During the secondary reflow heating, the conductive bonding material in the electronic component sometimes re-melts. In that case, the melted conductive bonding material enters a space in the electronic component to cause a short-circuit between the electrodes. The state is described with reference to FIGS. 1A and 1B. FIG. 1A is a schematic sectional view illustrating a state where the space is formed in the electronic component during the secondary reflow heating. FIG. 1B is a schematic sectional view illustrating a state where the melted conductive bonding material enters the space in the electronic component to cause a short-circuit between the electrodes.

When a former conductive bonding material is used for mounting of the chip component, the semiconductor component, and the like in the electronic component, in an electronic component 100 having a wiring board 1, electrode pads 2 on the wiring board 1, conductive bonding materials 3, a component (e.g., a chip component) 5 connected to the wiring board 1 through the conductive bonding materials 3, electrodes 4 of the component 5, and a sealing resin 6 which seals the component 5 as illustrated in FIG. 1A, cracking occurs in the sealing resin 6 or a small space 7 is formed between the component 5 and the sealing resin 6 due to deformation or the like of the sealing resin 6 caused by a change in the volume (expansion) due to melting of the conductive bonding materials 3 during the secondary reflow for soldering the electronic component 100 to an external printed-circuit board. Due to the fact that the melted conductive bonding materials 3 flow into the small space 7 due to capillarity or the like, the electrodes 4 of the component 5 or the electrodes 4 of the components 5 are electrically connected to cause a short-circuit as illustrated in FIG. 1B (hereinafter also referred to as a “flash phenomenon”).

The conductive bonding material of this embodiment contains copper particles coated with either Ga or Ga alloy and either Sn particles or Sn alloy particles, in which the Ga or the Ga alloy which is a low melting point metal functions as a diffusion promoter, so that the Cu particles are certainly diffused into the Sn particles or the Sn alloy particles, and then the Cu particles and the Sn particles or the Sn alloy particles form a Cu—Sn intermetallic compound, whereby the melting point increases. As a result, the conductive bonding material may be precluded from re-melting during secondary reflow heating, high bonding strength may be maintained, and a short-circuit between electrodes of a component or electrodes of components due to flow of the melted conductive bonding material may be certainly precluded.

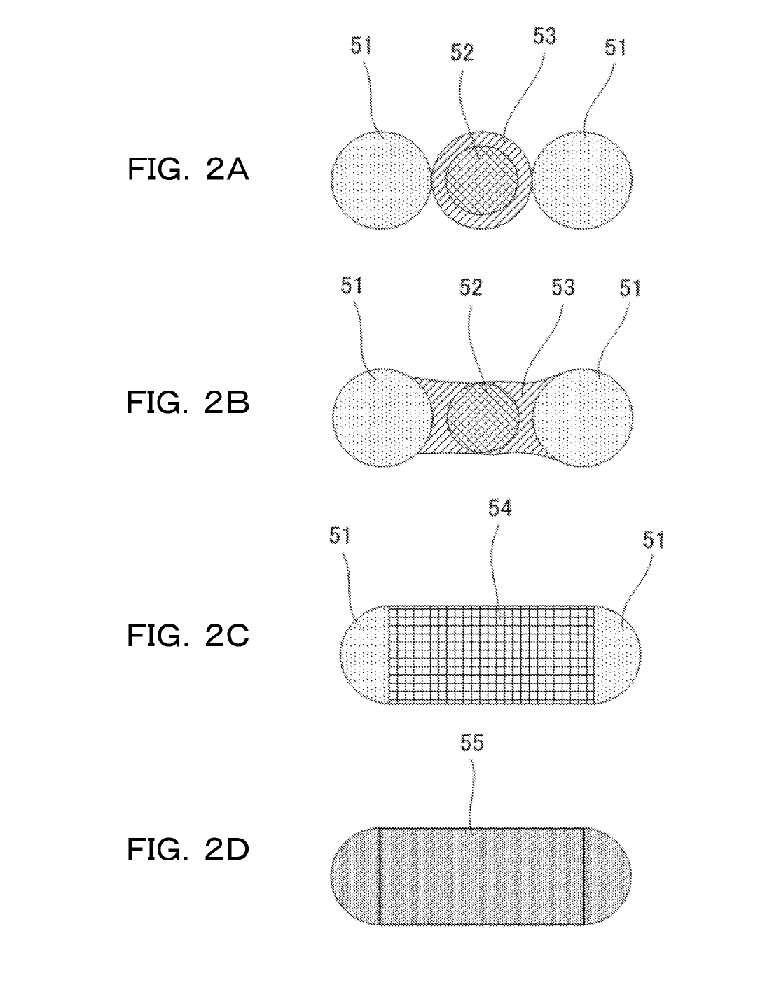

Herein, the bonding principle by the conductive bonding material of this embodiment is described with reference to FIGS. 2A to 2D.

As illustrated in FIG. 2A, Sn particles or Sn alloy particles 51, a Cu particle 52 coated with Ga or Ga alloy 53, and a flux (not illustrated) are kneaded to thereby produce a solder paste as the conductive bonding material.

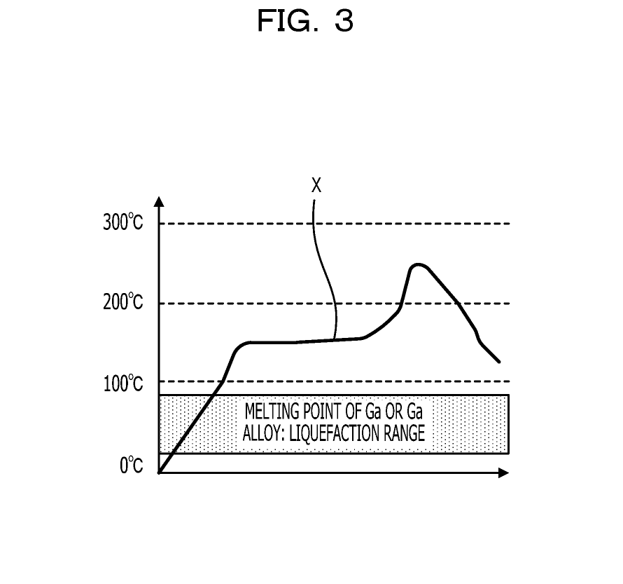

As illustrated in FIG. 2B, when primary reflow heating is carried out, the Ga or the Ga alloy 53 which is a low melting point metal is liquefied when the temperature reaches a low-temperature region (90° C. or lower) in a temperature profile X of the primary reflow heating as illustrated in FIG. 3.

Next, the Cu particles are diffused by the liquefied Ga, and then a Cu—Ga alloy 54 is formed (FIG. 2C).

Next, the contact area of the Sn particles or the Sn alloy particles 51 and the Cu—Ga alloy 54 increases, and then Cu components are rapidly diffused in the Sn particles or the Sn alloy particles by a diffusion promotion action of the Ga. Thereafter, the Ga is replaced with Sn, and then a Cu—Sn alloy 55 is widely formed (FIG. 2D). The Ca is present in a state where the Ga is separated from the Cu—Sn alloy. As a result, the melting point of the conductive bonding material may be shifted to a high temperature side, so that the conductive bonding material does not re-melt during the secondary reflow heating. Therefore, a short-circuit between electrodes of a component or electrodes of components due to flow of the melted conductive bonding material may be precluded.

Since the conductive bonding material of this embodiment does not re-melt during the secondary reflow heating for mounting an electronic component on an external printed-circuit board or the like, may maintain high bonding strength, and may preclude the occurrence of a short-circuit between electrodes, the conductive bonding material of this embodiment may be used for various fields using a conductive bonding material and may be preferably used for an electronic component of this embodiment and an electronic device of this embodiment described below.

Electronic Component

The electronic component of this embodiment at least has a wiring board, a component, a sealing resin, and a terminal, and may further contain other components. The wiring board has an electrode pad. The component has a plurality of electrodes, in which the plurality of electrodes are connected to the electrode pad through the conductive bonding material of this embodiment.

Wiring Board

The shape, structure, and size of the wiring board are not particularly limited and may be selected as appropriate according to the purpose. As the shape, a plate shape and the like are mentioned. The structure may be a single layer structure or a laminated structure. The size may be selected as appropriate according to the size of the electrode layer and the like.

Mentioned as a substrate in the wiring board are, for example, a glass substrate, a quartz substrate, a silicon substrate, a SiO₂ film-covered silicon substrate; a polymer substrate, such as epoxy resin, phenol resin, a polyethylene terephthalate substrate, a polycarbonate substrate, a polystyrene substrate, and a polymethyl methacrylate substrate, and the like.

These substances may be used alone or in combination of two or more kinds thereof. Among the above, the substrate is preferably selected from the glass substrate, the quartz substrate, the silicon substrate, and the SiO₂ film-covered silicon substrate, and the silicon substrate and the SiO₂ film-covered silicon substrate are particularly preferable. The substrate may be a synthesized one or a commercially-available item as appropriate.

The thickness of the substrate is not particularly limited and may be selected as appropriate according to the purpose and is preferably 100 μm or more and more preferably 500 μm or more.

The size of the wiring board is not particularly limited and may be selected as appropriate according to the purpose. For example, substrates and the like having a size in the range of a length of 10 mm to 200 mm, a width of 10 mm to 200 mm, and a thickness of 0.5 mm to 5 mm are mentioned.

The shape of the surface of the wiring board on which the components are mounted is not particularly limited and may be selected as appropriate according to the purpose. For example, a square shape, a rectangular shape, a round shape and the like are mentioned.

As the wiring board, a wiring circuit board on which a wiring pattern is formed is used. The circuit board may be a single-layer circuit board (single-layer printed-circuit board) or may be a multilayer circuit board (multilayer printed-circuit board).

Mentioned as metal constituting the electrode of the circuit board is metal, such as Cu, Ag, Au, Ni, Sn, Al, Ti, Pd, and Si, for example. Among the above, Cu, Ag, and Au are particularly preferable. These metals may be formed as a surface portion of an electrode metal on the wiring board by various kinds of treatment, such as plating or pasting. When the conductive bonding material is applied to the electrode metal on the wiring board, the electrode metal on the wiring board is generally subjected to surface coating treatment in order to achieve good connection between the conductive bonding material and the electrode metal on the wiring board. For example, in the case of a copper electrode, a thin film of Sn, Au, Ni, or the like formed by plating is formed on the electrode as an example. In particular, the metals mentioned above other than Au, the metal surface is easily oxidized. Therefore, such metals are preferably surface treated with flux or the like before applying a solder paste or precoated with flux, plated with various metals, or coated with solder.

Component

The component is not particularly limited and may be selected as appropriate according to the purpose insofar as the component has a plurality of electrodes. For example, a chip component, a semiconductor component, and the like are mentioned. The component is mounted on the wiring board.

The chip component is not particularly limited and may be selected as appropriate according to the purpose. For example, a capacitor, a resistance, and the like are mentioned.

The semiconductor component is not particularly limited and may be selected as appropriate according to the purpose. For example, an integrated circuit, a large scale integrated circuit, a transistor, a thyristor, a diode, and the like are mentioned. These components may be used alone or in combination of two or more kinds thereof.

The size of the components is not particularly limited and may be selected as appropriate according to the purpose. For example, a 1608 type (1.6 mm×0.8 mm×0.8 mm), a 1005 type (1 mm×0.5 mm×0.5 mm), a 0603 type (0.6 mm×0.3 mm×0.3 mm), and the like are mentioned.

In the electronic component, a plurality kinds of the components are usually mounted on the wiring board.

In the electronic component, not all of the components are soldered in some cases. At least some of the components may be soldered and some components may be subjected to leadframe connection.

Conductive Bonding Material Supply Method

A method for supplying a conductive bonding material is not particularly limited and may be selected as appropriate according to the purpose insofar as the conductive bonding material may be applied with a fixed thickness or a fixed application amount. For example, screen printing, transfer printing, dispenser discharge, an ink jet method, and the like are mentioned.

In the screen printing, a printing machine using a mask plate may be used. The printing machine typically has a mechanism for fixing a wiring board or an electronic component, a mechanism for positioning a metal mask and electrodes of a substrate or terminals of an electronic component, and a mechanism for pressure-welding the mask plate to the wiring board or the electronic component, and then printing the conductive bonding material from an opening with a squeegee for application from the top of the mask to the electrodes of the wiring board or the terminals of the electronic component present under the mask.

As the mask plate, there are various materials, such as a mesh type and a metal type. A metal mask type which is applicable to a wide range of particle sizes and which is easily cleaned in a process is generally widely used.

The transfer printing is a method for disposing a fixed amount of the conductive bonding material to electrodes of a wiring board or terminals of an electronic component by forming a flat coating film of the conductive bonding material with a fixed coating film thickness with a squeegee or the like having a fixed clearance, wiping the coating film by a stamper, and then stamping the same to the electrodes of the wiring board or the terminals of the electronic component, and a transfer printing device exclusive for the method is used.

The transfer printing device has an application mechanism for applying a flat coating film, a mechanism for fixing the wiring board and positioning the electrode position of the wiring board, and a mechanism for driving a stamper in a three dimensional manner to perform wiping and transfer-stamping. In the transfer printing, the application amount is more likely to vary as compared with screen printing and caution is given to continuous operation, such as cleaning management of the stamper. Therefore, as the printing method, screen printing is mainly used.

The dispenser discharge is a method including discharging a fixed amount of the conductive bonding material to the electrodes on the wiring board or the terminals of the electronic component, and a dispenser device is used. The dispenser is a device for pressing out a fixed amount of the conductive bonding material from a needle at the top of a syringe by applying pressure for discharge to the conductive bonding material stored in the syringe on demand and a device for discharging and applying an appropriate amount of the conductive bonding material onto the electrodes by driving the syringe itself in a three dimensional manner, and determining the position of the electrode portion on the wiring board.

There is a disadvantage in that the thickness of the conductive bonding material itself is difficult to decrease due to the method including discharging from a needle as compared with screen printing. However, a loss of the conductive bonding material in a process is small and the discharge position and the discharge amount are variable by a program. Therefore, the conductive bonding material may be applied to the wiring board and the electronic component with a level difference and irregularities to which the printing mask plate is difficult to be pressure-welded.

The ink jet method is a method including discharging the conductive bonding material from a fine nozzle, and applying the same to the electrodes on the wiring board or the terminals of the electronic component.

In a state where the electronic component or the wiring board is disposed on the conductive bonding material supplied to the electrodes of the wiring board or the terminals of the electronic component, a fixed temperature is applied for bonding.

For the bonding, a reflow device having a furnace which suits to solder heat treatment, a high temperature bath, or the like is used, for example.

The heat treatment using the reflow device is preferably performed at 100° C. to 170° C. for 10 minutes to 120 minutes, for example.

Sealing Resin

The sealing resin is not particularly limited and may be selected as appropriate according to the purpose insofar as the resin is resin covering the component.

The material of the sealing resin is not particularly limited and may be selected as appropriate according to the purpose. For example, thermosetting resin, such as phenol resin, melamine resin, epoxy resin, and polyester resin, and the like are mentioned.

A method for sealing the components is not particularly limited and may be selected as appropriate according to the purpose. For example, potting in which the components are sealed in such a manner as to wrap the same, transfer molding using the thermosetting resin, and the like are mentioned.

The sealing with the sealing resin in the electronic component may be performed only to the components or may be performed to the entire surface of the wiring board.

Terminal

The terminal is not particularly limited and may be selected as appropriate according to the purpose insofar as the terminal is a terminal for connecting the wiring in the wiring board to an external substrate. For example, a lead wire and the like are mentioned. The electronic component has a plurality of the terminals.

The shape of the terminal is not particularly limited and may be selected as appropriate according to the purpose. For example, a wire shape and the like are mentioned.

The material of the lead wire is not particularly limited and may be selected as appropriate according to the purpose. For example, gold, silver, copper, and the like are mentioned.

Electronic Device

The electronic device of this embodiment at least has an electronic component, and may further contain other components. The electronic component is the electronic component of this embodiment.

The electronic component is mounted on the electronic device by soldering the terminals of the electronic component to the electronic device.

The electronic device of this embodiment is not particularly limited and may be selected as appropriate according to the purpose. For example, processing units, such as a personal computer and a server; communication devices, such as a cellular phone and a radio; office machines, such as a printer and a copying machine; AV devices, such as a television and an audio component; home electrical appliances, such as an air-conditioner and a refrigerator; and the like are mentioned.

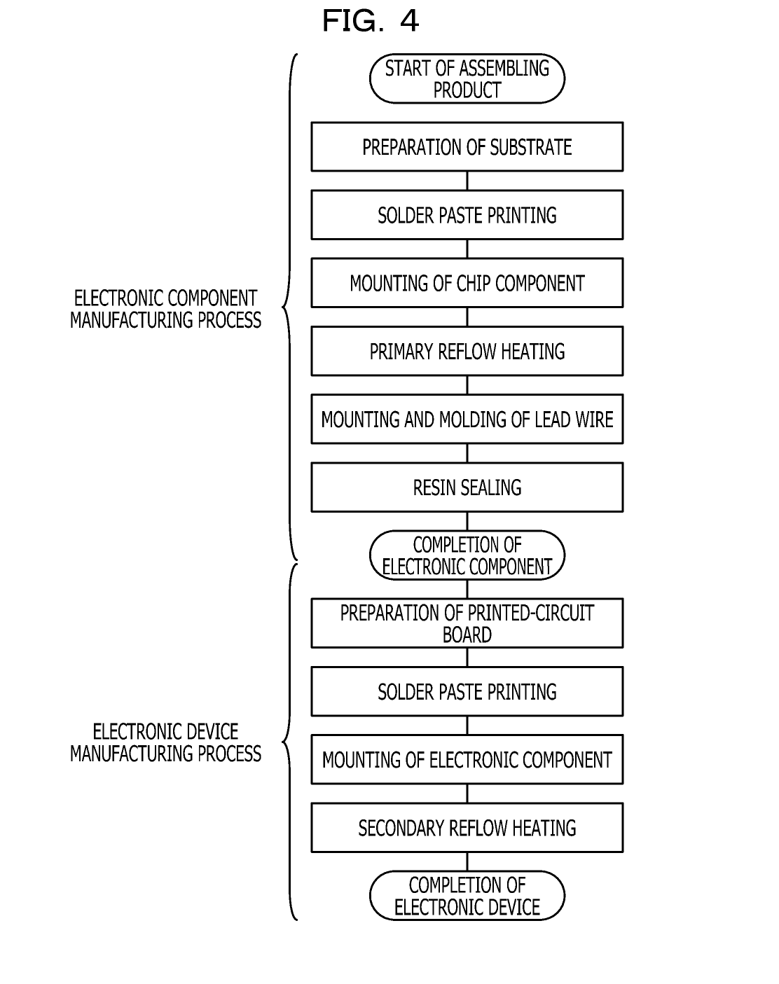

Herein, FIG. 4 is a flow chart illustrating an example of a manufacturing process of the electronic component and the electronic device of this embodiment. The manufacturing process of the electronic component and the electronic device of FIG. 4 includes an electronic component manufacturing process and an electronic device manufacturing process. The electronic component is produced in the electronic component manufacturing process. The electronic device is produced in the electronic device manufacturing process.

Electronic Component Manufacturing Process

The electronic component manufacturing process includes a substrate preparation process, a printing process of a solder paste as a conductive bonding material, a chip component mounting process, a primary reflow heating process, a lead wire mounting and molding process, and a resin sealing process.

In the substrate preparation process, a wiring board having an electrode pad is prepared.

In the printing process of the solder paste, a solder paste as the conductive bonding material of this embodiment is printed to the wiring board, and then the conductive bonding material is placed on the electrode pad.

In the chip component mounting process, components, such as a chip component, are disposed on the electrode pad.

In the primary reflow heating process, primary reflow heating is performed for soldering the components.

In the lead wire mounting and molding process, the lead wire is mounted, and then molded.

In the resin sealing process, the components are mounted by performing sealing with a sealing resin (primary mounting). Thus, the electronic component is produced.

Electronic Device Manufacturing Process

The electronic device manufacturing process includes a printed-circuit board preparation process, a printing process of a solder paste as a conductive bonding material, a mounting process of the produced electronic component, and a secondary reflow heating process.

In the printed-circuit board preparation process, a printed-circuit board having a lead terminal is prepared.

In the printing process of the solder paste, a solder paste as the conductive bonding material is applied onto the printed-circuit board by screen printing, and the conductive bonding material is placed on the lead terminal.

In the mounting process of the electronic component, the lead wire of the electronic component is disposed on the lead terminal on the printed-circuit board.

In the secondary reflow heating process, the electronic component is soldered to the printed-circuit board by performing secondary reflow heating (secondary mounting). Thus, the electronic device is produced.

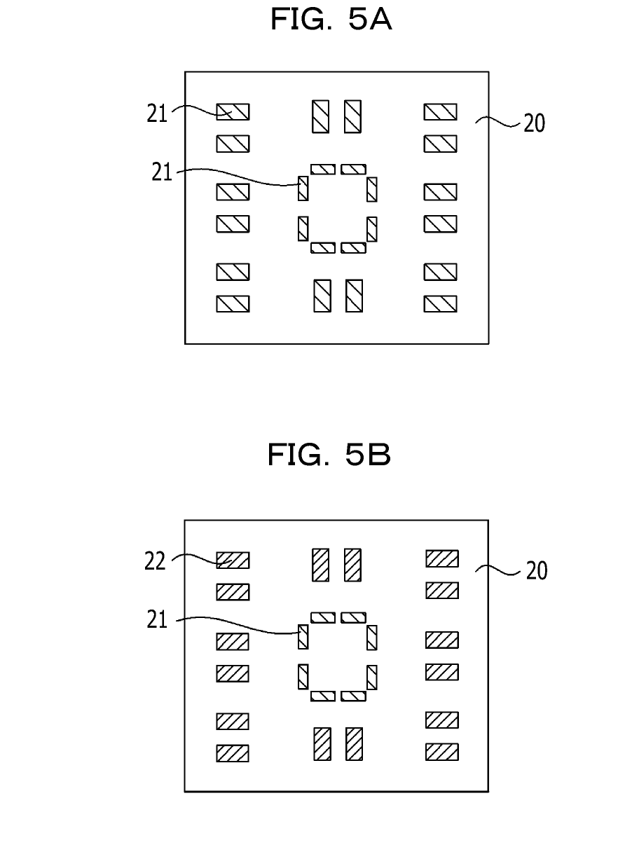

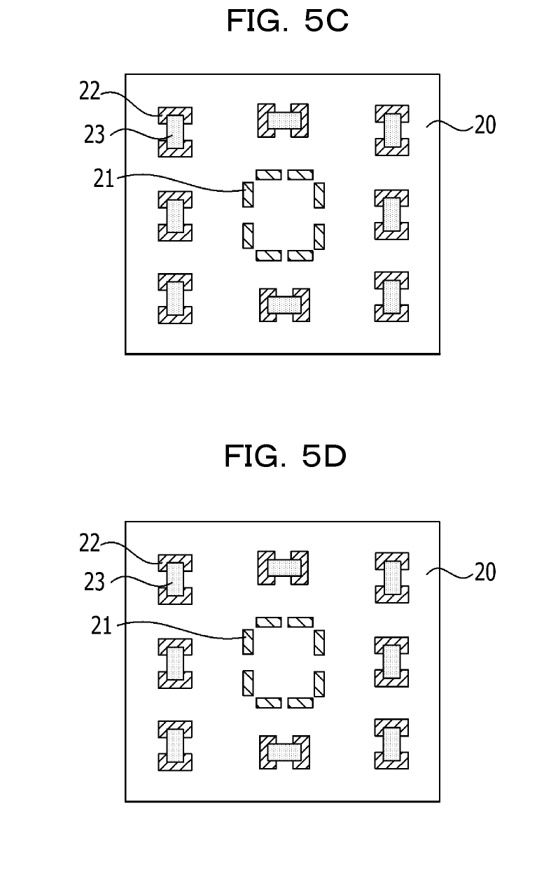

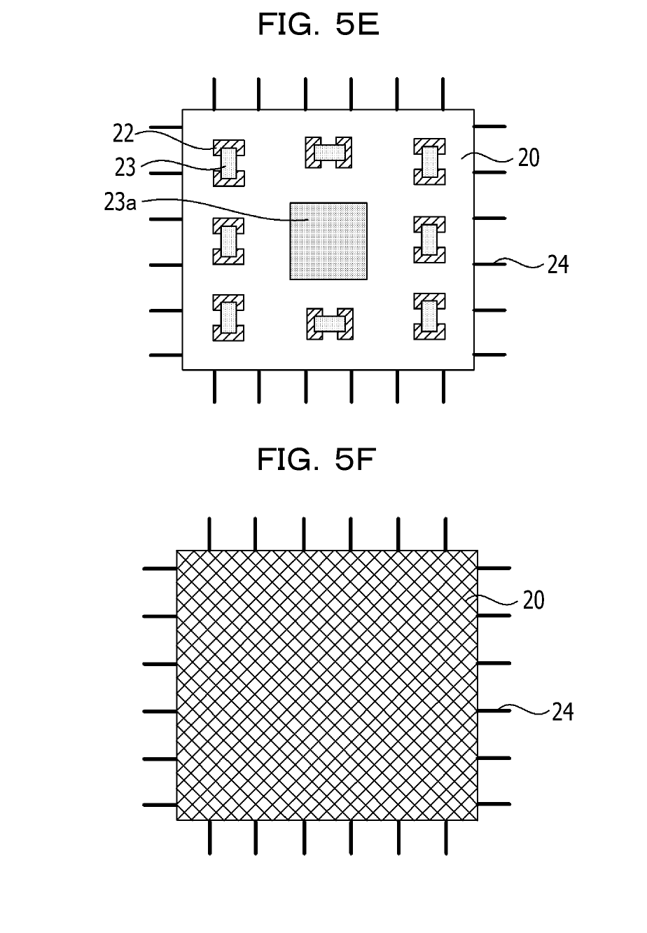

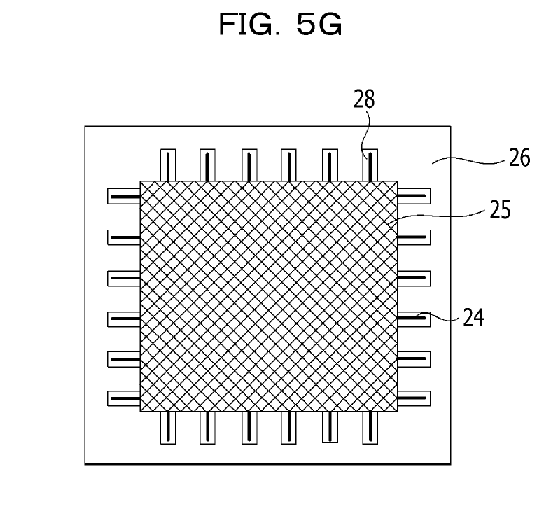

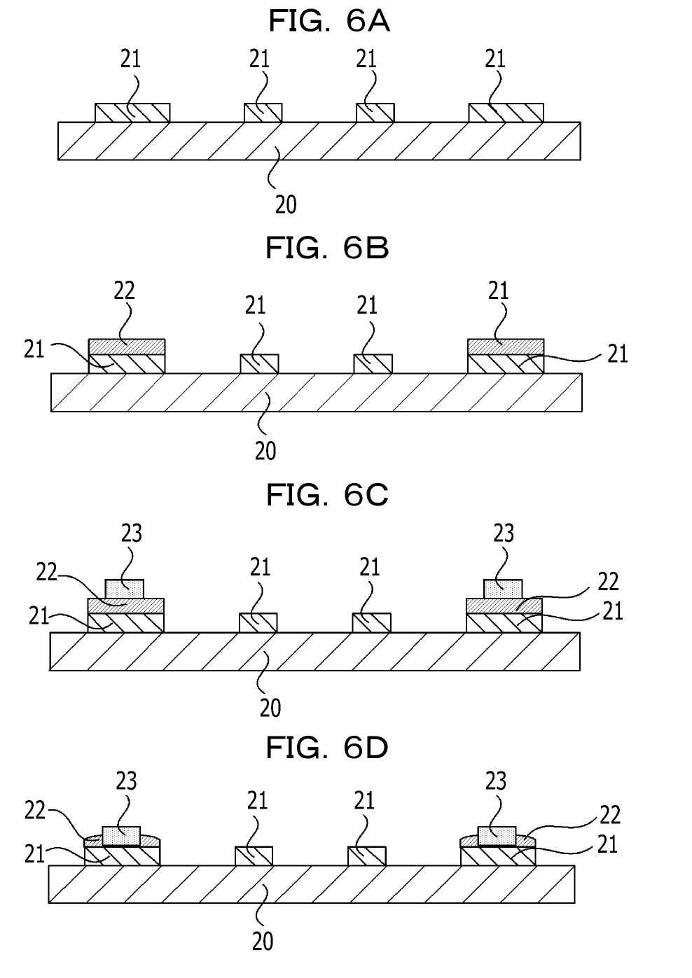

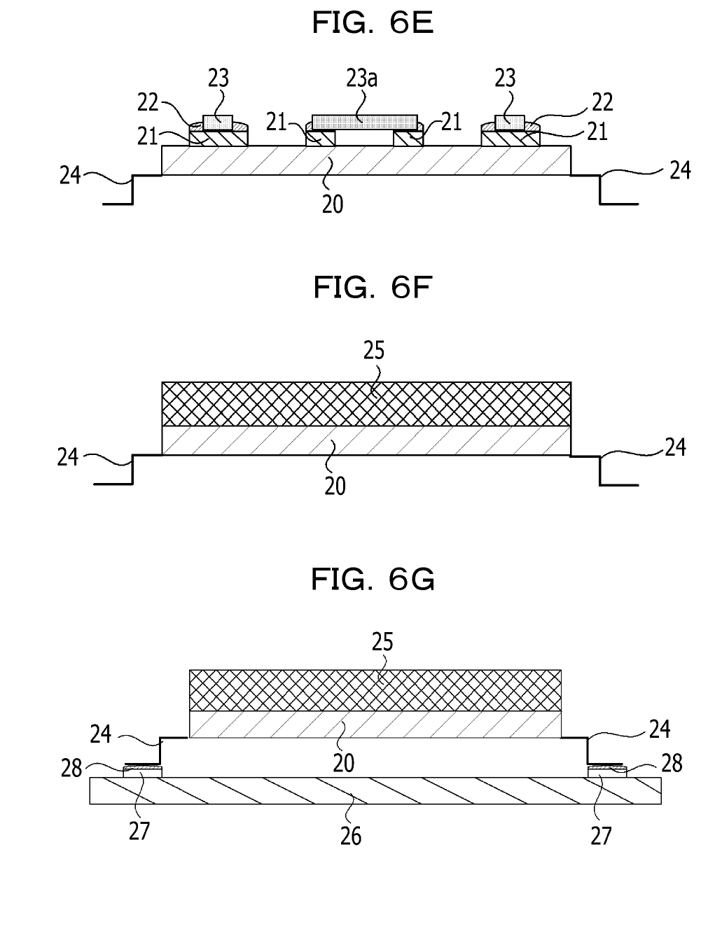

Herein, FIGS. 5A to 5G are schematic sectional views for explaining an example of the manufacturing process of the electronic component and the electronic device of this embodiment. FIGS. 6A to 6G are schematic top views for explaining an example of the manufacturing process of the electronic component and the electronic device of this embodiment.

Hereinafter, the method for manufacturing the electronic component of this embodiment and the method for manufacturing the electronic device of this embodiment are described with reference to FIGS. 5A to 5G and FIGS. 6A to 6G.

First, as illustrated in FIG. 5A and FIG. 6A, a wiring board 20 having electrode pads 21 is prepared.

Next, as illustrated in FIG. 5B and FIG. 6B, a solder paste as a conductive bonding material 22 of this embodiment is printed to the wiring board 20, and the conductive bonding material 22 is placed on the electrode pads 21. The printing method is not particularly limited and may be selected as appropriate according to the purpose. For example, screen printing and the like are mentioned.

Next, as illustrated in FIG. 5C and FIG. 6C, a plurality of components 23 are disposed on the electrode pads 21 through the conductive bonding material 22.

Next, as illustrated in FIG. 5D and FIG. 6D, primary reflow heating is performed for soldering the components 23. The primary reflow heating is preferably performed at a peak temperature of 160° C. for 10 minutes, for example.

Next, as illustrated in FIG. 5E and FIG. 6E, another component 23a may be mounted, lead wires 24 are mounted, and then molding may be performed.

Next, as illustrated in FIG. 5F and FIG. 6F, the components 23 are mounted by performing sealing with a sealing resin 25 (primary mounting). Thus, the electronic component is produced.

The sealing resin is not particularly limited and may be selected as appropriate according to the purpose insofar as the resin is resin capable of covering the components. For example, thermosetting resin, such as phenol resin, melamine resin, epoxy resin, and polyester resin, and the like are mentioned.

Next, as illustrated in FIG. 5G and FIG. 6G, a printed-circuit board 26 having lead terminals 27 is prepared, a solder paste as a conductive bonding material is applied onto the printed-circuit board 26 by screen printing, and then the conductive bonding material 28 is mounted on the lead terminals 27. Then, the lead wires 24 of the electronic component are disposed on the lead terminals 27 on the printed-circuit board 26, and then secondary reflow heating is performed to solder the electronic component to the printed-circuit board 26 (secondary mounting). The secondary reflow heating is preferably performed at a peak temperature of 235° C. for 5 minutes, for example. Thus, the electronic device is produced.

### EXAMPLES

Hereinafter, the embodiment is more specifically described with reference to Examples, but the embodiment is not limited to the Examples.

In the following Examples, the average thickness of a Ga or Ga alloy coating film and the volume average particle diameter of Cu or Cu alloy particles were measured as follows.

Method for Measuring Average Thickness of Ga or Ga Alloy Coating Film

The average thickness of the Ga or Ga alloy coating film was measured by a fluorescent X ray analyzing method using a device described below.
Measuring device name: Fluorescent X-ray plating thickness meter
Manufacturing company name: Alex Corporation

The fluorescent X ray analysis method is a method utilizing generated peculiar X-rays (fluorescent X-rays) obtained by irradiating a substance with X-rays. The fluorescent X-rays are rays obtained when the emitted X-rays repel the inner shell electrons of a substance constituent atom to the outer shell, and then the outer shell electrons fall in a vacant space (hole), the surplus energy is emitted as an electromagnetic field. Since the fluorescent X-rays have energy peculiar to an element, the qualitative analysis may be achieved from the energy under the Mosley rule and the quantification may be achieved from the X ray intensity (Number of photons) of the energy.

Volume Average Particle Diameter of Cu or Cu Alloy Particles

The volume average particle diameter of the Cu or Cu alloy particles was measured by measuring the particle diameter of each measurement population using a device described below, and then determining the volume average particle diameter from the particle size distribution measurement results.
Measuring device name: Laser scattering diffraction type particle size distribution meter CILAS1090
Manufacturing company name: Nippon Selas Co., Ltd.

In the laser scattering diffraction type (Fraunhofer diffraction, Mie scattering method), the particle diameter is specified from the light intensity distribution pattern. To that end, the correspondence relationship between the particle diameter and the light intensity distribution pattern is determined beforehand. In order to determine the correspondence relationship, the Fraunhofer diffraction theory and the Mie scattering theory are used. More specifically, these theories are used for determining the type of a light intensity distribution pattern generated by particles of various sizes and are memorized in a computer beforehand as a huge amount of parameter tables (mathematical tables).

### Manufacturing Example 1

### Production of Cu Particles Coated with Ga or Ga Alloy

First, melted Cu was granulated by an atomizing method, cooled, and then collected. The obtained Cu particles were classified into arbitrary particle diameter ranges using a sieve.

Next, the Cu particles were immersed in a plating bath containing a Ga electroless plating liquid. A Ga plating coating film was formed, washed, and then dried. Thus, Cu particles coated with Ga were produced. Cu particles coated with Ga alloy were also produced similarly as described above.

### Manufacturing Example 2

### Production of Sn Alloy Particles

Melted Sn alloy (Sn-3Ag-0.5Cu) was granulated by an atomizing method, cooled, and then collected. The obtained Sn alloy particles were classified into arbitrary particle diameter ranges using a sieve to produce Sn alloy (Sn-3Ag-0.5Cu) particles. Sn alloy (Sn-58Bi-1.0Ag) particles were also produced similarly as described above.

### Example 1

### Production of Conductive Bonding Material

A metal component containing Ga-covered Cu particles in which Cu particles having a volume average particle diameter of 20 μm were subjected to Ga electroless plating with an average thickness of 1 μm and Sn alloy particles with a volume average particle diameter of 20 μm and a flux component were kneaded according to the following formulation to thereby produce a solder paste as a conductive bonding material.

Formulation:

<Flux component>: 10% by mass
Polymerized rosin (pine resin) . . . 48% by mass
Diphenyl guanidine HBr (active agent) . . . 2% by mass
Hardened castor oil (thixotropy agent) . . . 5% by mass
Dibromohexane (aliphatic compound) . . . 5% by mass
α-terpineol (solvent) . . . 40% by mass

<Metal component>: 90% by mass
Ga-covered Cu particles . . . 30% by mass
Sn alloy particles (Sn-3Ag-0.5Cu) . . . 70% by mass

### Example 2

### Production of Conductive Bonding Material

A solder paste as a conductive bonding material was produced in the same manner as in Example 1, except using Ga-covered Cu particles in which Cu particles with a volume average particle diameter of 20 μm were subjected to Ga electroless plating with an average thickness of 3 μm in Example 1.

### Example 3

### Production of Conductive Bonding Material

A solder paste as a conductive bonding material was produced in the same manner as in Example 1, except using Ga-covered Cu particles in which Cu particles with a volume average particle diameter of 20 μm were subjected to Ga electroless plating with an average thickness of 10 μm in Example 1.

### Example 4

### Production of Conductive Bonding Material

A solder paste as a conductive bonding material was produced in the same manner as in Example 1, except using Ga-covered Cu particles in which Cu particles with a volume average particle diameter of 0.5 μm were subjected to Ga electroless plating with an average thickness of 1 μm in Example 1.

### Example 5

### Production of Conductive Bonding Material

A solder paste as a conductive bonding material was produced in the same manner as in Example 1, except using Ga-covered Cu particles in which Cu particles with a volume average particle diameter of 10 μm were subjected to Ga electroless plating with an average thickness of 1 μm in Example 1.

### Example 6

### Production of Conductive Bonding Material

A solder paste as a conductive bonding material was produced in the same manner as in Example 1, except using Ga-covered Cu particles in which Cu particles with a volume average particle diameter of 30 μm were subjected to Ga electroless plating with an average thickness of 1 μm in Example 1.

### Example 7

### Production of Conductive Bonding Material

A solder paste as a conductive bonding material was produced in the same manner as in Example 1, except changing the mixed ratio of the metal component in Example 1 as descried below.

<Metal component>: 90% by mass
Ga-covered Cu particles . . . 20% by mass
Sn alloy particles (Sn-3Ag-0.5Cu) . . . 80% by mass

### Example 8

### Production of Conductive Bonding Material

A solder paste as a conductive bonding material was produced in the same manner as in Example 1, except changing the mixed ratio of the metal component in Example 1 as descried below.

<Metal component>: 90% by mass
Ga-covered Cu particles . . . 40% by mass
Sn alloy particles (Sn-3Ag-0.5Cu) . . . 60% by mass

### Example 9

### Production of Conductive Bonding Material

A solder paste as a conductive bonding material was produced in the same manner as in Example 1, except changing the mixed ratio of the metal component in Example 1 as descried below.

<Metal component>: 90% by mass
Ga-covered Cu particles . . . 50% by mass
Sn alloy particles (Sn-3Ag-0.5Cu) . . . 50% by mass

### Example 10

### Production of Conductive Bonding Material

A solder paste as a conductive bonding material was produced in the same manner as in Example 1, except changing the metal component in Example 1 as descried below.

<Metal component>: 90% by mass
Ga-covered Cu particles . . . 30% by mass
Sn alloy particles (Sn-58Bi-1.0Ag) . . . 70% by mass

### Example 11

### Production of Conductive Bonding Material

A solder paste as a conductive bonding material was produced in the same manner as in Example 1, except changing the metal component in Example 1 as descried below.

<Metal component>: 90% by mass
Ga-covered GaCu alloy particles (Ga:Cu=30% by mass:70% by mass, Melting point: About 800° C.) . . . 30% by mass
Sn alloy particles (Sn-3Ag-0.5Cu) . . . 70% by mass

### Example 12

### Production of Conductive Bonding Material

A solder paste as a conductive bonding material was produced in the same manner as in Example 1, except changing the metal component in Example 1 as descried below.

<Metal component>: 90% by mass
Ga-3.7Cu alloy-covered Cu particles . . . 30% by mass
Sn alloy particles (Sn-3Ag-0.5Cu) . . . 70% by mass

### Example 13

### Production of Conductive Bonding Material

A solder paste as a conductive bonding material was produced in the same manner as in Example 1, except changing the metal component in Example 1 as descried below.

<Metal component>: 90% by mass
Ga-7.2Sn alloy-covered Cu particles . . . 30% by mass
Sn alloy particles (Sn-3Ag-0.5Cu) . . . 70% by mass

### Example 14

### Production of Conductive Bonding Material

A solder paste as a conductive bonding material was produced in the same manner as in Example 1, except changing the metal component in Example 1 as descried below.

<Metal component>: 90% by mass
Ga-5.0Ni alloy-covered Cu particles . . . 30% by mass
Sn alloy particles (Sn-3Ag-0.5Cu) . . . 70% by mass

### Example 15

### Production of Conductive Bonding Material

A solder paste as a conductive bonding material was produced in the same manner as in Example 1, except changing the metal component in Example 1 as descried below.

<Metal component>: 90% by mass
Ga-3.0Au alloy-covered Cu particles . . . 30% by mass
Sn alloy particles (Sn-3Ag-0.5Cu) . . . 70% by mass

### Example 16

### Production of Conductive Bonding Material

A solder paste as a conductive bonding material was produced in the same manner as in Example 1, except changing the metal component in Example 1 as descried below.

<Metal component>: 90% by mass
Ga-4.0Ag alloy-covered Cu particles . . . 30% by mass
Sn alloy particles (Sn-3Ag-0.5Cu) . . . 70% by mass

### Example 17

### Production of Conductive Bonding Material

A solder paste as a conductive bonding material was produced in the same manner as in Example 1, except changing the metal component in Example 1 as descried below.

<Metal component>: 90% by mass
Ga-4.0AI alloy-covered Cu particles . . . 30% by mass
Sn alloy particles (Sn-3Ag-0.5Cu) . . . 70% by mass

### Comparative Example 1

### Production of Conductive Bonding Material

A solder paste as a conductive bonding material was produced in the same manner as in Example 1, except changing the metal component in Example 1 as descried below.

<Metal component>: 90% by mass
Cu particles (Volume average particle diameter of 20 μm) . . . 15% by mass
Ga particles (Volume average particle diameter of 20 μm) . . . 15% by mass
Sn alloy particles (Sn-3Ag-0.5Cu) . . . 70% by mass

As in Comparative Example 1, when Cu simple substance particles, Ga simple substance particles, and Sn alloy particles (solder) were mixed and heated, a diffusion reaction of the Ga and the Sn preferentially occurred, so that the Sn entered the grain boundary in a portion where the Ga concentration was high to cause embrittlement, whereby the bonding reliability of the solder alloy remarkably decreased.

In the embodiment, an action which suppresses the formation of a portion where the Ga concentration is noticeably high is achieved by adjusting the Ga coating film thickness of the Cu particles.

### Comparative Example 2

### Production of Conductive Bonding Material

A solder paste as a conductive bonding material was produced in the same manner as in Example 1, except changing the metal component in Example 1 as descried below.

<Metal component>: 90% by mass
Sn alloy particles (Sn-3Ag-0.5Cu) . . . 100% by mass

### Comparative Example 3

### Production of Conductive Bonding Material

A solder paste as a conductive bonding material was produced in the same manner as in Example 1, except changing the metal component in Example 1 as descried below.

<Metal component>: 90% by mass
Ga-covered Cu particles . . . 100% by mass

### Comparative Example 4

### Production of Conductive Bonding Material

A solder paste as a conductive bonding material was produced in the same manner as in Example 1, except changing the metal component in Example 1 as descried below.

<Metal component>: 90% by mass
91.1Sn-3.9Cu-1.0Ga-4.0In alloy which was obtained by reproducing Example 2 of Japanese Laid-open Patent Publication. No. 10-291087 . . . 100% by mass

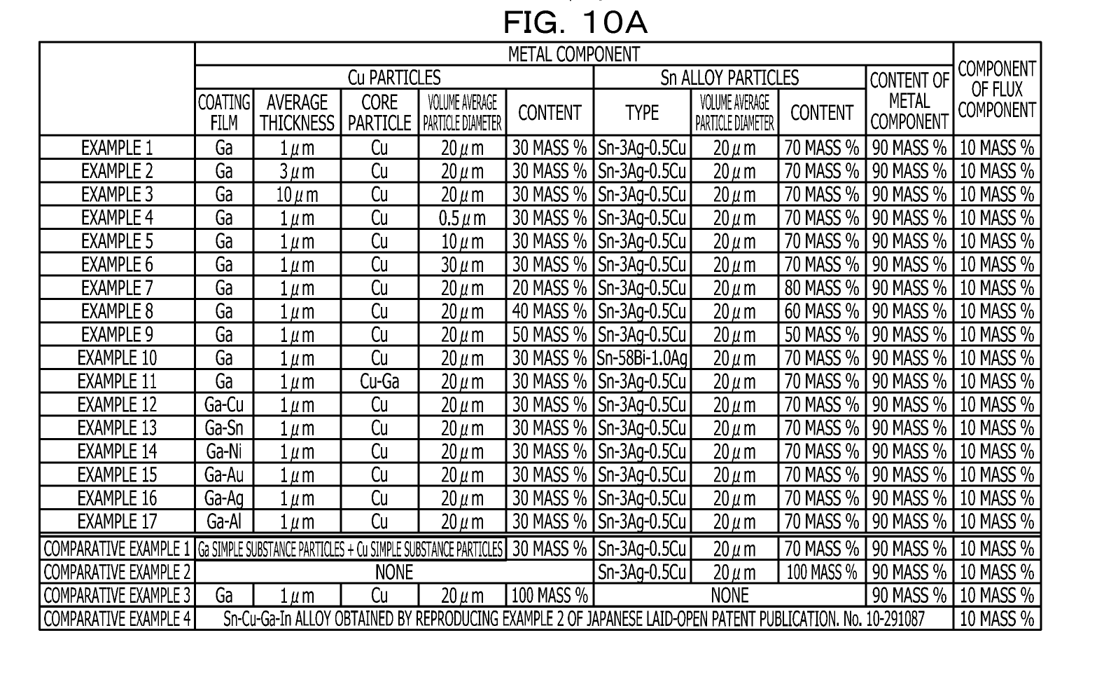

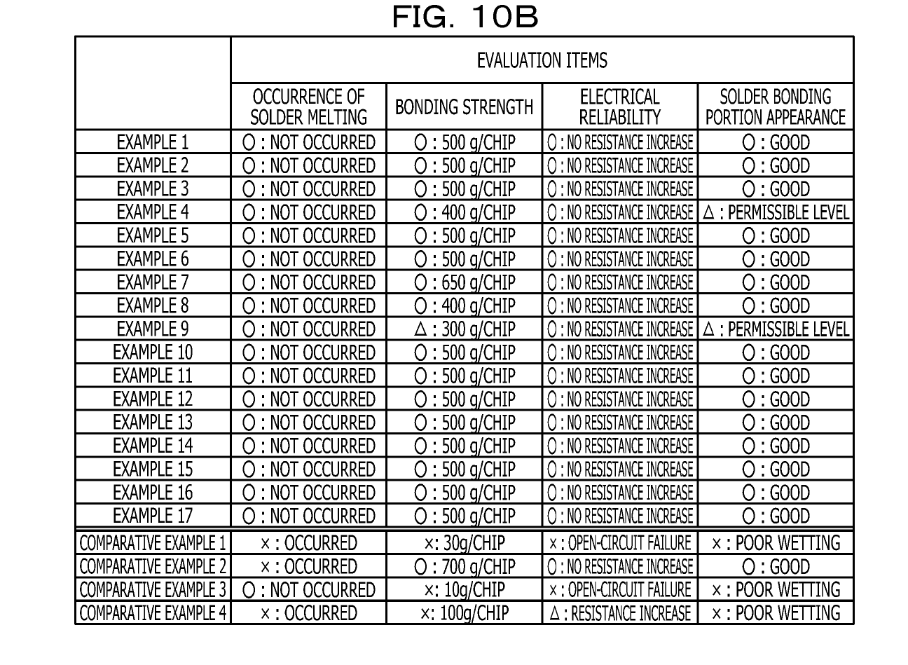

Next, the properties of each of the produced conductive bonding materials were evaluated as follows. The results are illustrated in FIGS. 10A and 10B.

Evaluation Method of Occurrence of Solder Melting

Each of the produced conductive bonding materials was screen printed onto a wiring board on which a predetermined copper pattern was formed. Then, chip components were placed on the screen printed conductive bonding material, and then primary reflow heating was carried out at a peak temperature of 160° C. for 10 minutes in a nonoxidizing atmosphere, so that the chip component was primarily mounted on the wiring board.

Then, the wiring board was washed, a sealing resin (epoxy adhesive) was applied onto the wiring board, the resin was cured by heating at 150° C. for 1 hour, and then the wiring board with the rein was allowed to stand for 24 hours under high temperature and high humidity (85° C./85% RH), thereby producing an electronic component.

The produced electronic components were subjected to secondary reflow heating at a peak temperature of 235° C. for 5 minutes (secondary mounting).

The electronic components after the secondary mounting were visually observed to confirm the presence or absence of solder melting between the chip components and in the same component. Then, the solder melting was evaluated as follows. The number of the observed chip components is 400.

Evaluation Criteria

◯: No solder melting occurred.

x: Solder melting occurred.

Evaluation Method of Bonding Strength

The produced electronic components were subjected to secondary reflow heating at a peak temperature of 235° C. for 5 minutes (secondary mounting) in the same manner as in the evaluation method of occurrence of solder melting. The bonding strength of a solder bonding portion of the electronic components after the secondary mounting was measured using a shear strength test machine (Dage series 4000 Multi-Function Bondtester), and then evaluated based on the following evaluation criteria.

Evaluation Criteria

◯: Bonding strength is 400 g/CHIP or more.

Δ: Bonding strength is 200 g/CHIP or more and lower than 400 g/CHIP.

x: Bonding strength is lower than 200 g/CHIP.

Evaluation Method of Electrical Reliability

The produced electronic components were subjected to secondary reflow heating at a peak temperature of 235° C. for 5 minutes (secondary mounting) in the same manner as in the evaluation method of occurrence of solder melting. The electrical resistance of a solder bonding portion of the electronic components after the secondary mounting was measured using a resistance meter (FLUKE 77 Digital Multimeter), and the electrical reliability was evaluated based on the following evaluation criteria.

Evaluation Criteria

◯: The electrical resistance value did not increase.

Δ: The electrical resistance value increased.

x: Open-circuit failure occurred.

Evaluation Method of Solder Bonding Portion Appearance

The produced electronic components were subjected to secondary reflow heating at a peak temperature of 235° C. for 5 minutes (secondary mounting) in the same manner as in the evaluation method of occurrence of solder melting. The appearance of the solder bonding portion of the electronic components after the secondary mounting was visually observed, and then evaluated based on the following evaluation criteria.

Evaluation Criteria

◯: Good

Δ: Permissible level

x: Poor solder wetting

### Example 18

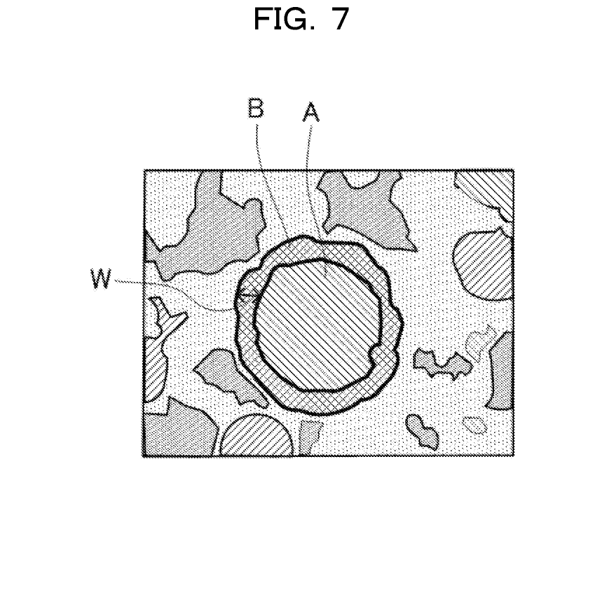

Using the conductive bonding material of Example 1, metal mapping (Energy dispersion type X-ray microanalyzer (EDS), manufactured by JEOL Co., Ltd., JSA6390LA) around the Cu particles after the reflow heating (Peak temperature of 235° C.) was measured, and the diffusibility (diffusion length) of Cu was evaluated. The diffusion length is an average value obtained by arbitrarily measuring ten places. The results are illustrated in FIG. 7. In FIG. 7, A denotes the Cu particle, B denotes a Cu3Sn layer formed by diffusion of Cu, and W denotes the width (diffusion length) of the Cu3Sn layer.

### Comparative Example 5

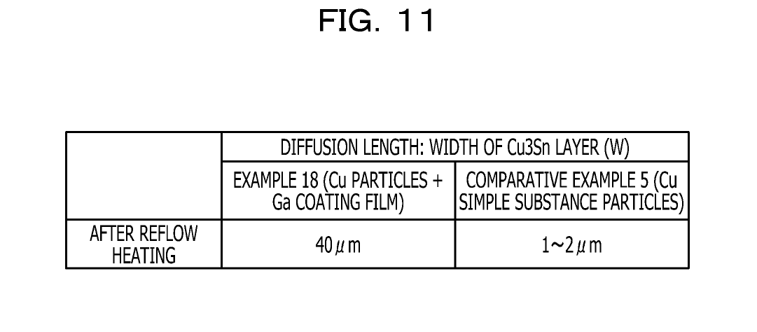

The diffusibility (diffusion length) of Cu was evaluated in the same manner as in Example 18, except using Cu simple substance particles on which a Ga coating film was not formed in the conductive bonding material of Example 1. The results are illustrated in FIG. 11.

The results of FIG. 11 indicate that the copper diffusion amount (melting amount) sharply increases in the Cu particles coated with Ga of Example 18 as compared with the Cu simple substance particles of Comparative Example 5 and that an alloy of Cu and Sn was formed.

### Example 19

### Production of Electronic Component and Production of an Electronic Device

An electronic component and an electronic device were produced as follows using the conductive bonding material produced in Example 1.

—Production of Electronic Component—

First, a copper pattern (Pad size: 0.3 mm×0.3 mm, Distance between pads: 0.2 mm (pitch)) was formed on a wiring board (Size: 110 mm×110 mm×1.0 mm in thickness). The conductive bonding material of Example 1 was printed onto the wiring board using a metal screen plate and a metal squeegee. For the metal screen plate, one having a pad opening of 100% and a plate thickness of 150 μm was used. A chip component (0603 chip component, Sn electrode) was placed on the printed conductive bonding material, and then subjected to primary reflow heating at a peak temperature of 160° C. for 10 minutes in a nonoxidizing atmosphere (Oxygen concentration of lower than 100 ppm) to thereby primarily mount the chip component on the substrate.

Then, the wiring board was washed, a sealing resin (epoxy adhesive) was applied onto the wiring board, the resin was cured by heating at 150° C. for 1 hour, and then the wiring board with the rein was allowed to stand for 24 hours under high temperature and high humidity (85° C./85% RH), thereby producing an electronic component. The connection of lead wires was omitted.

Production of Electronic Device

Next, a solder paste was applied onto a printed-circuit board having lead terminals by screen printing, and solder was placed on the lead terminals. Then, the lead wires of the produced electronic component were placed on the lead terminal on the printed-circuit board, and then secondary reflow heating was carried out at a peak temperature of 235° C. for 5 minutes, thereby soldering the electronic component to the printed-circuit board. Thus, an electronic device was produced.

—Evaluation—

The obtained electronic device was evaluated in the same manner as in Example 1. Then, the occurrence of solder melting between the chip components and in the same and one component was not observed, the bonding strength of the solder bonding portion of the electronic component was 400 g/CHIP or more, and an increase in the electrical resistance value of the solder bonding portion of the electronic component was not observed. The appearance of the solder bonding was also good.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A conductive bonding material, comprising:
copper particles coated with either gallium or gallium alloy; and
either tin particles or tin alloy particles.

2. The conductive bonding material according to claim 1, wherein
the gallium alloy is any one of Ga—Ni alloy, Ga—Cu alloy, Ga—Sn alloy, and Ga—Au alloy.

3. The conductive bonding material according to claim 1, wherein
a volume average particle diameter of the copper particles is 0.5 μm or more and 30 μm or lower.

4. The conductive bonding material according to claim 1, wherein
an average thickness of a coating film containing either the gallium or the gallium alloy is 0.5 μm or more and 10 μm or lower.

5. The conductive bonding material according to claim 1, wherein
the copper particles contain an alloy of gallium and copper.

6. The conductive bonding material according to claim 1, wherein
a mixed ratio of the copper particles coated with either the gallium or the gallium alloy and the tin particles or the tin alloy particles is 20:80 to 50:50 in terms of a mass ratio.

7. The conductive bonding material according to claim 1, wherein
the tin alloy particles are either Sn—Bi—X alloy particles or Sn—Cu—X alloy particles (X is any one of Ag, Ni, Zn, Pd, and In.).

8. The conductive bonding material according to claim 7, wherein
the tin alloy particles are either Sn-58Bi-1.0Ag alloy particles or Sn-0.5Cu-3.0Ag alloy particles.

9. The conductive bonding material according to claim 1, wherein
a content of a metal component is 50% by mass or more and 95% by mass or lower based on the conductive bonding material.

10. The conductive bonding material according to claim 1, comprising
a flux component containing at least any one of an epoxy flux material and a rosin flux material.

11. The conductive bonding material according to claim 10, wherein
a content of the flux component is 5% by mass or more and 50% by mass or lower based on the conductive bonding material.

12. An electronic component, comprising:
a wiring board having electrode pads;
a component mounted on the wiring board and having a plurality of electrodes;
a sealing resin covering the component; and
a plurality of terminals coupled to a wiring line in the wiring board to an external substrate, wherein
the plurality of electrodes being coupled to the electrode pads through a conductive bonding material containing copper particles coated with either gallium or gallium alloy particles and either tin particles or tin alloy particles.

13. The electronic component according to claim 12, wherein
the sealing resin is at least any one of phenol resin, melamine resin, epoxy resin, and polyester resin.

14. An electronic device, comprising:
an electronic component, the electronic component including:
a wiring board having electrode pads,
a component mounted on the wiring board and having a plurality of electrodes,
a sealing resin covering the component, and
a plurality of terminals coupled to a wiring line in the wiring board to an external substrate, wherein
the plurality of electrodes being coupled to the electrode pads through a conductive bonding material containing copper particles coated with either gallium or gallium alloy particles and either tin particles or tin alloy particles.

15. The electronic device according to claim 14, which is any one of a processing unit, a communication device, an office machine, an audio visual device, and a home electrical appliance.
